(19) United States
(12) Patent Application Publication
(10) Pub. No.: US 2022/0279060 A1
(43) Pub. Date: Sep. 1, 2022

(54) CASING STRUCTURE OF ELECTRONIC DEVICE

(71) Applicant: SHENZHEN IDATA MACHINE VISION TECHNOLOGY CO., LTD., Szenzhen, Guangdon (CN)

(72) Inventors: Dongsheng WANG, Guangzhou, Guangdong (CN); Jing LIU, Shenzhen, Guangdong (CN); Lijing ZHANG, Changsha, Hunan (CN); Zhenxi WANG, Shenzhen, Guangdong (CN); Xianfu LIU, Shenzhen, Guangdong (CN)

(21) Appl. No.: 17/624,567

(22) PCT Filed: Jun. 29, 2020
(86) PCT No.: PCT/CN2020/098695

§ 371 Date: Jan. 3, 2022

(30) Foreign Application Priority Data
Jul. 1, 2019 (CN) 201910586568.9

(51) Int. Cl. H04M 1/02; H05K 5/00; H05K 5/02

(52) U.S. Cl. CPC H04M 1/0262; H05K 5/0086; H05K 5/0217

(57) ABSTRACT

The present disclosure provides a casing structure of an electronic device including a first casing and a second casing, the second casing is detachably installed on the first casing, the second casing is provided with an approximately square main body part, the main body part is provided with a first end and a second end which are opposite, and the first end can be supported on the first casing to rotate so that the first casing and the second casing are in a relatively open state or buckled state, the casing structure of an electronic device can include at least one limiting part and at least one butt joint part, wherein the at least one limiting part extends downwards from the middle of the main body part and is located between the first end and the second end.

### TECHNICAL FIELD

The present disclosure relates to a casing structure of an electronic device, in particular to a casing structure of an electronic device, and the casing structure is used for preventing gaps from being generated between mutually assembled casings.

### BACKGROUND

An existing hand-held terminal comprises a rear casing and a battery cover which are buckled with each other, in order to guarantee the buckling stability of the rear casing and the battery cover, the rear casing and the battery cover are usually locked through a locking piece, namely, the locking piece is installed on the rear casing, and the rear casing and the battery cover are locked together through matching of a lock hook on the locking piece and a lock groove in the battery cover. When the battery needs to be taken out, the battery can be taken out only by sliding the locking piece so that the locking hook is separated from the locking groove and then opening the battery cover. According to the structure, the tension between the middle part of the battery cover and the rear casing is weak, so that the battery cover is easy to bulge and deform, a gap is easy to generate between the battery cover and the rear casing, and the waterproof and dustproof effects are poor.

In the industry, a circle of buckles are additionally arranged on the periphery of the battery cover to be connected with clamping grooves in the rear casing, so that the tensioning force of the battery cover and the rear casing is increased. However, when the battery is replaced, due to the fact that the tensioning force of the battery cover and the rear casing is large, user operation is not convenient; and in the repeated opening and closing process of the battery cover, the buckles repeatedly rub against the side wall of the rear casing, and the buckles are easily abraded, so that the tensioning force of the battery cover and the rear casing is gradually reduced, and a gap is still easily generated between the battery cover and the rear casing. More importantly, when the hand-held terminal is impacted by external force, the battery cover is easily extruded and deformed, so that the buckle is separated from the clamping groove, the buckle cannot automatically reset into the clamping groove, and a large gap is formed between the battery cover and the rear casing.

Aiming at the problems, the present disclosure provides a novel casing structure of an electronic device, and a novel method and novel technical means are adopted to solve the problems.

### SUMMARY

Aiming at the problems faced by the background art, the present disclosure aims to provide a casing structure of an electronic device, and the casing structure is used for preventing gaps from being generated between mutually assembled casings.

To achieve the above purpose, the present disclosure adopts the following technological means:

The present disclosure provides a casing structure of an electronic device, casing structure being provided with a first casing and a second casing, the second casing being detachably installed on the first casing, the second casing being provided with an approximately square main body part, the main body part being provided with a first end and a second end which are opposite, the first end being capable of being supported on the first casing to rotate so that the first casing and the second casing are in a relatively open state or buckled state, and the casing structure of an electronic device comprising:

at least one limiting part and at least one butt joint part, wherein the at least one limiting part extends downwards from the middle of the main body part and is located between the first end and the second end, and the limiting part is provided with a limiting surface which faces upwards and is obliquely arranged towards the first end; the at least one butt joint part is located at the position, corresponding to the limiting part, of the first casing and used for being in butt joint with the limiting part, and the butt joint part is provided with a butt joint surface obliquely arranged towards the oblique lower part and used for being in butt joint with the limiting surface; and when the second casing rotates from the open state to the buckled state, the limiting part rotates by taking the first end as an axis, so that the limiting surface approximately moves to the oblique lower part of the butt joint part along an arc track to be in contact with the butt joint surface.

Optionally, at least one buckle extends from the edge of the first end to the second end, at least one clamping groove is formed in the first casing and used for being clamped with the at least one buckle, the second casing rotates by taking the edge of the first end or the buckle as a supporting point to form the virtual rotating shaft, and the limiting surface is approximately located on a cylindrical surface by taking the virtual rotating shaft as an axis.

Optionally, when the first casing and the second casing are in the buckled state, the limiting part and the butt joint part do not interfere with each other.

Optionally, when the second casing and the first casing are in the buckled state, the limiting part and the butt joint part do not interfere with each other.

Optionally, the size of the limiting part is gradually reduced from the root to the free end, a through hole is formed in the first casing and is adjacent to the butt joint part, and the free end of the limiting part penetrates through the through hole.

Optionally, the number of the limiting parts is two, and the two limiting parts are located on the two opposite sides of the main body part respectively.

Optionally, a locking mechanism is arranged close to the second end and used for locking the second end with the first casing.

Optionally, the locking mechanism comprises a locking piece installed on the first casing or the second casing and clamping hooks arranged on the second casing or the first casing, and the locking piece can move between a locking position and an unlocking position so as to be separated from or clamped with the clamping hooks.

Optionally, the electronic device is a mobile terminal, the first casing is a battery casing, the second casing is a battery cover, and the first casing and the second casing are jointly used for accommodating a battery.

Optionally, when the first casing and the second casing are in the buckled state, the limiting surface is approximately parallel to the butt joint surface.

Compared with the prior art, the present disclosure has the following beneficial effects:

The limiting part is arranged on the second casing, the limiting part extends downwards from the middle of the main body part and is located between the first end and the second end, the limiting surface arranged on the limiting part faces upwards and is obliquely arranged towards the first end, the butt joint part is arranged at the position, corresponding to the limiting part, of the first casing and used for being in butt joint with the limiting part, and the butt joint surface arranged on the butt joint part faces downwards and is obliquely arranged towards the limiting part so as to be in butt joint with the limiting surface; and when the second casing is supported on the first casing by the first end and rotates from the open state to the buckled state, the limiting part rotates by taking the supporting point of the first end as an axis, so that the limiting surface approximately moves to the oblique lower part of the butt joint part along an arc track to be in contact with the butt joint surface. Even if the electronic device is impacted by external force, the second casing is extruded and deformed, and the limiting part moves upwards, the limiting part can return to an original position due to the fact that the acting force of the butt joint part on the limiting part faces the oblique lower part, a gap cannot be generated between the second casing and the first casing or the gap can be automatically eliminated, and dust or water drops and other sundries are prevented from entering the electronic device; and due to the fact that the limiting surface approximately moves to the oblique lower part of the butt joint part along the arc track, in the buckling process of the second casing and the first casing, the limiting part and the butt joint part cannot generate strong interference, abrasion cannot be generated even if long-term repeated opening and closing are conducted, when the second casing is opened, the interference force of the first casing does not need to be resisted, and opening and closing are convenient and labor-saving.

### BRIEF DESCRIPTION OF THE DRAWINGS

FIG. 1 is a space diagram of an electronic device in the present disclosure;

FIG. 2 is an exploded stereoscopic diagram of an electronic device in the present disclosure;

FIG. 3 is a section view in A-A direction in FIGS. 1; and

FIG. 4 is a schematic diagram when a second casing is in an open state in the figure.

Reference signs in the detailed description of the embodiments:

| | | | | |
|---|---|---|---|---|
| Electronic | First casing 1 | Clamping | Butt joint | Butt joint |
| device 100 | | groove 11 | part 12 | surface 121 |
| Through hole 13 | Second | Main body | First end | Buckle 212 |
| | casing 2 | part 21 | 211 | |
| Second end 213 | Clamping | Limiting | Limiting | Locking |
| | hook 214 | part 22 | surface 221 | mechanism 3 |
| Locking piece 31 | Push | Protruding | | |
| | button 311 | block 312 | | |

### DETAILED DESCRIPTION OF THE EMBODIMENTS

To facilitate better understanding of the purposes, structures, features, effects and the like of the present disclosure, the present disclosure is further described in conjunction with the attached figures and detailed description of the embodiments.

The electronic device 100 in the present disclosure may comprise at least one of a smart phone, a tablet personal computer (PC), a mobile phone, a video phone, an electronic book reader, a desktop PC, a notebook computer, a netbook computer, a workstation, a server, a personal digital assistant (PDA), a portable multimedia player (PMP), an MP3 player, a medical device, a camera and a wearable device. The wearable device may comprise at least one application accessory type of device (such as a watch, a ring, a bracelet, an anklet, a necklace, glasses, contact lenses) and a head-mounted-device (HMD), a textile, or a clothing-integrated device (such as an electronic garment). According to various embodiments, the electronic device may comprise a television (TV), a digital video disk (DVD) player, an audio player, an air conditioner, a cleaner, an oven, a microwave oven, a washing machine, an air purifier, a set top box, a home automation control panel, a security control panel, a media box (such as Samsung HomeSync™, Apple TV™, or Google TV™), a game console (such as Xbox™, Play S tation™), an electronic dictionary, an electronic key, a camcorder and an electronic frame.

According to an alternative embodiment, the electronic device may comprise at least one of medical devices (such as portable medical measuring devices including a blood glucose meter, a heart rate monitor, a blood pressure monitor and a body temperature thermometer, a magnetic resonance angiography (MRA) device, a magnetic resonance imaging (MRI) device, a computed tomography (CT) device, a video camera and a microwave scanner), a navigation device, a global navigation satellite system (GNSS), an event data recorder (EDR), a flight data recorder (FDR), an automotive infotainment device, marine electronics (such as a marine navigation system and a gyrocompass), aviation electronics (avionics), a security device, an automotive mainframe, an industrial or household robot, a drone, an automatic teller machine (ATM), a point of sales (POS) terminal and an Internet-of-things (IoT) device (such as a light bulb, a sensor, a water sprinkler system, a fire alarm system, a temperature controller, a street lamp, a toaster, fitness equipment, a hot water tank, a heater and a boiler). According to an embodiment of the present disclosure, the electronic device may comprise at least one of furniture, a part of a building/structure, a part of a vehicle, an electronic board, an electronic signature receiving device, a projector, and a sensor (such as a water meter, an electricity meter, a gas meter and an electric wave meter). According to various embodiments of the present disclosure, the electronic device may be flexible or a combination of at least two of the above-mentioned devices. According to an embodiment of the present disclosure, the electronic device is not limited to the above-mentioned devices. In the present disclosure, the term “user” may mean a person who uses an electronic device or a device (such as an artificial intelligence electronic device) that uses an electronic device.

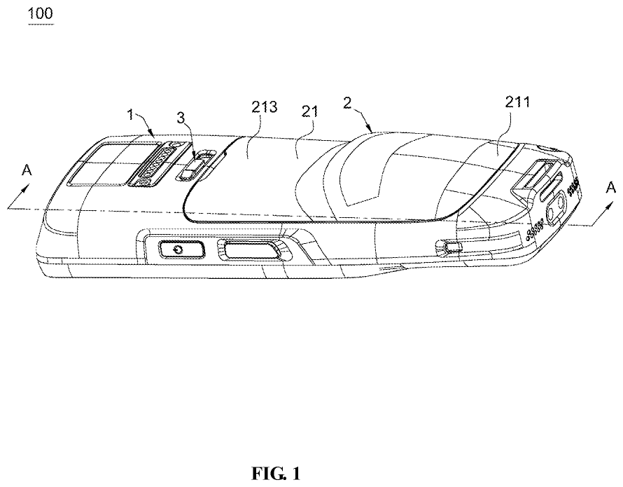

As shown in FIG. 1, a casing structure of an electronic device 100 in the present disclosure is described by taking a PDA in a mobile terminal as an example.

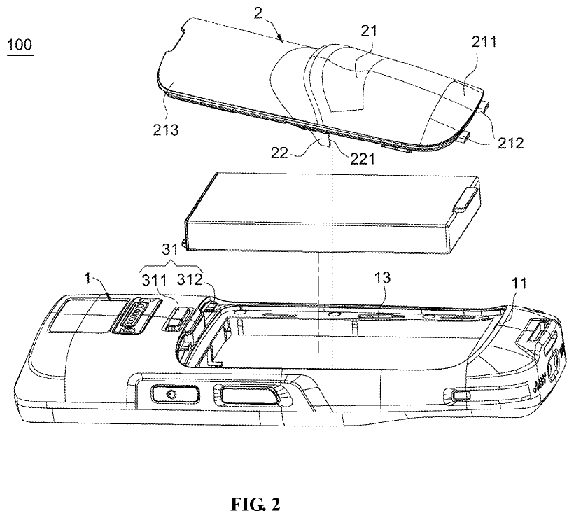

As shown in FIG. 1 and FIG. 2, the electronic device 100 is placed with the back side facing upwards, and the electronic device 100 comprises a first casing 1 and a second casing 2, and the second casing 2 is detachably installed on the first casing 1. In the embodiment, the first casing 1 is a battery casing, the second casing 2 is a battery cover, and the first casing and the second casing are jointly surrounded to form a battery jar (unmarked, similarly hereinafter) and used for accommodating a battery (unmarked, similarly hereinafter).

The second casing 2 is provided with an approximately square main body part 21, along the length direction of the main body part 21 the main body part 21 is provided with a first end 211 and a second end 213 which are opposite, the first end 211 can be supported on the first casing 1 to rotate so that the first casing 1 and the second casing 2 are in a relatively open state or buckled state. Two buckles 213 extend from the edge of the first end 211 to the second end 213, two clamping grooves 11 are formed in the first casing 1 and used for being clamped with the two buckles 212.

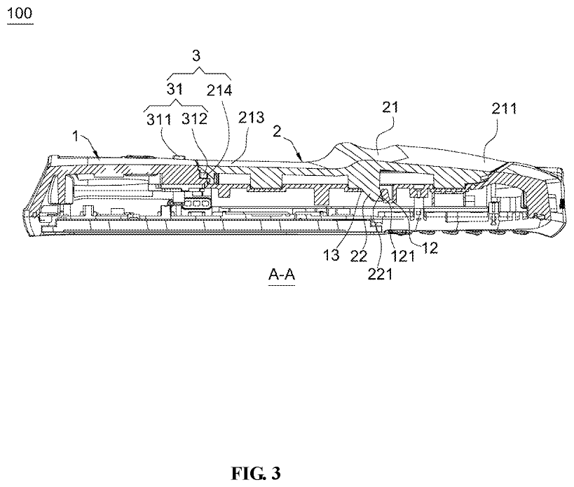

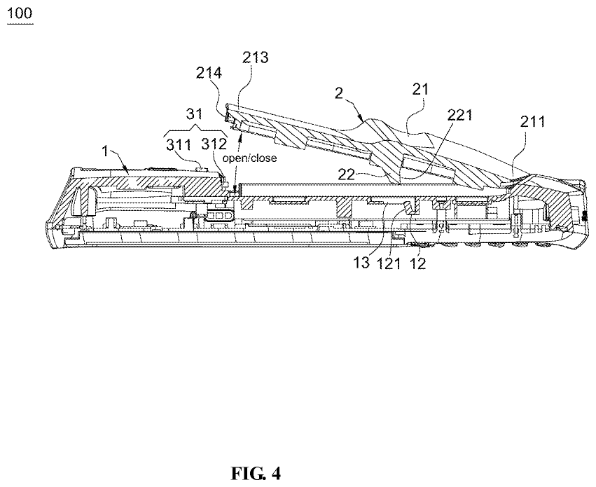

As shown in FIG. 3 and FIG. 4, the middle positions of the left side and the right side of the lower surface of the main body part 21 respectively extend downwards to form a limiting part 22, and the size of the limiting part 22 is gradually reduced from the root to the free end, so that the limiting part 22 is approximately in an inverted trapezoid shape. A limiting surface 221 is formed on the surface, facing the first end 211, of the limiting part 22, the limiting surface 221 is slightly oblique upwards, and the limiting surface 221 is arranged to be a plane in order to facilitate forming machining of a mold; in other embodiments, more limiting parts 22 can be arranged as required, the closer the limiting parts 22 are to the first end 211, the smaller the inclination is, namely, the larger the included angle with the vertical direction is, the farther the limiting parts 22 are from the first end 211, the larger the inclination is, namely, the closer the limiting surface 221 is to the vertical shape; and in other embodiments, the limiting surface 221 may be configured as a curved surface. A butt joint part 12 is arranged at the position, corresponding to each limiting part 22, of the first casing 1 and used for being in butt joint with the limiting part 22, the butt joint part 12 is provided with a butt joint surface 121 obliquely arranged towards the oblique lower part, and when the first casing 1 is in a buckled state, the butt joint surface 121 is approximately parallel to the limiting surface 221; and a through hole 13 is formed in the first casing 1 to be adjacent to the butt joint part 12, and the through hole 13 is used for allowing the free end of the limiting part 22 to penetrate through.

A locking mechanism 3 is arranged on the electronic device 100 close to the second end 213 of the first casing 1 and used for locking the second end 213 of the second casing 2 with the first casing 1, and then the second casing 2 is installed and fixed on the first casing 1 in cooperation with the limiting part 22 and the two buckles 212 of the first end 211. In the embodiment, the locking mechanism 3 comprises two clamping hooks 214 arranged at the end of the second end 213 and a locking piece 31 installed on the first casing 1, the locking piece 31 comprises a push button 311 and two protruding blocks 312 located at the two ends of the push button 311, the two protruding blocks 312 are used for being clamped with the two clamping hooks 214 respectively, and the locking piece 31 can move between a locking position and an unlocking position by pushing the push button 311 left and right, so that the protruding block 312 is separated from or clamped with the clamping hook 214. In other embodiments, the locking piece 31 may be installed on the second casing 2, while the first casing 1 is correspondingly provided with two clamping hooks 214 to cooperate with the locking piece 31. In other embodiments, the locking piece 31 may be arranged to be of a cam structure or other suitable structures.

When the battery is installed, the battery is firstly installed in the battery jar, then the two buckles 212 of the first end 211 are aligned with the two clamping grooves 11 in the first casing 1 to be inserted, the first end 211 is supported on the first casing 1, according to different structures, the edge of the first end 211 can be supported on the first casing 1, and the two buckles 212 can also be supported on the first casing 1. In the embodiment, the second casing 2 is supported on the first casing 1 by using the edge of the first end 211 as a supporting point, and at the moment, the second casing 2 and the first casing 1 are in a relatively open state. The second casing 2 is rotated to be in a buckled state with the first casing 1, in the whole process, the second casing 2 rotates by taking the edge of the first end 211 as an axis to form a virtual rotating shaft, and the limiting surface 221 is approximately located on a cylindrical surface by taking the virtual rotating shaft as the axis, namely, the distances between all points on the limiting surface 221 and the virtual rotating shaft are approximately the same, the limiting surface 221 roughly performs circular motion along the cylindrical surface, the free end of the limiting part 22 penetrates through the through hole 13 to the oblique lower part of the butt joint part 12, the limiting surface 221 and the butt joint surface 121 form surface contact, and in the whole process, the limiting surface 221 and the butt joint surface 121 do not interfere with each other. The push button 311 is pushed, so that the locking piece 31 slides to the locking position, and the installation of the battery is completed.

When the electronic device 100 is impacted by the outside, the second casing 2 may deform, the middle of the second casing 2 is instantly bulged, a gap is formed between the second casing 2 and the first casing 1, the limiting surface 221 interferes with the butt joint surface 121, and the limiting surface 221 cannot be separated from the butt joint surface 121 when sliding upwards along the butt joint surface 121 due to the fact that the contact area of the limiting surface 221 and the butt joint surface 121 is large, and the butt joint surface 121 further generates an inclined downward acting force on the limiting surface 221, so that the limiting part 22 moves downwards to return to an original position, and the gap between the second casing 2 and the first casing 1 is eliminated.

In the embodiment, the first end 211 of the second casing 2 is positioned on the first casing 1 with the buckles 212; and in other embodiments, a hinge structure may be arranged at the first end 211 of the second casing 2 to hinge the first end 211 to the first casing 1.

The casing structure of an electronic device in the present disclosure has the following beneficial effects:

The limiting part 22 is arranged on the second casing 2, the limiting part 22 extends downwards from the middle of the main body part 21 and is located between the first end 211 and the second end 213, the limiting surface 221 arranged on the limiting part 22 faces upwards and is obliquely arranged towards the first end 211, the butt joint part 12 is arranged at the position, corresponding to the limiting part, of the first casing 22 and used for being in butt joint with the limiting part 22, and the butt joint surface 121 arranged on the butt joint part 12 faces downwards and is obliquely arranged towards the limiting part 22; and when the second casing 2 is supported on the first casing 1 by the first end 211 and rotates from the open state to the buckled state, the limiting part 22 rotates by taking the supporting point of the first end 211 as an axis, so that the limiting surface 221 approximately moves to the oblique lower part of the butt joint part 12 along an arc track to be in contact with the butt joint surface 121. Even if the electronic device 100 is impacted by external force, the second casing 2 is extruded and deformed, and the limiting part 22 moves upwards, the limiting part 22 can return to an original position due to the fact that the acting force of the butt joint part 12 on the limiting part 22 faces the oblique lower part, a gap cannot be generated between the second casing 2 and the first casing 1 or the gap can be automatically eliminated, and dust or water drops and other sundries are prevented from entering the electronic device 100; and due to the fact that the limiting surface 221 approximately moves to the oblique lower part of the butt joint part 12 along the arc track, in the buckling process of the second casing 2 and the first casing 1, the limiting part 22 and the butt joint part 12 cannot generate strong interference, abrasion cannot be generated even if long-term repeated opening and closing are conducted, when the second casing 2 is opened, the interference force of the first casing 1 does not need to be resisted, and opening and closing are convenient and labor-saving.

The above are only the description of preferred embodiments of the present disclosure and not intended to limit the patent scope of the present disclosure, and equivalent technical changes based on the specification and the attached figures of the present disclosure shall similarly fall within the scope of patent protection of the present disclosure.

1. A casing structure of an electronic device comprising a first casing and a second casing, the second casing being detachably installed on the first casing, the second casing being provided with an approximately square main body part, the main body part being provided with a first end and a second end which are opposite, the first end being capable of being supported on the first casing to rotate so that the first casing and the second casing are in a relatively open state or buckled state, and the casing structure of an electronic device comprising:
at least one limiting part, the at least one limiting part extending downwards from the middle of the main body part and being located between the first end and the second end, and the limiting part being provided with a limiting surface which faces upwards and being obliquely arranged towards the first end; and
at least one butt joint part, the at least one butt joint part being located at the position, corresponding to the limiting part, of the first casing and used for being in butt joint with the limiting part, and the butt joint part being provided with a butt joint surface obliquely arranged towards the oblique lower part and used for being in butt joint with the limiting surface, wherein
when the second casing rotates from the open state to the buckled state, the limiting part rotates by taking the first end as an axis to form a virtual rotating shaft, the limiting surface is approximately located on a cylindrical surface by taking the virtual rotating shaft as an axis, and the limiting surface approximately moves to the oblique lower part of the butt joint part along the cylindrical surface to be in contact with the butt joint surface.

2. The casing structure of an electronic device according to claim 1, wherein at least one buckle extends from the edge of the first end to the second end, at least one clamping groove is formed in the first casing and used for being clamped with the at least one buckle, and the second casing rotates by taking the edge of the first end or the buckle as a supporting point to form the virtual rotating shaft.

3. The casing structure of an electronic device according to claim 1, wherein when the first casing and the second casing are in the buckled state, the limiting part and the butt joint part do not interfere with each other.

4. The casing structure of an electronic device according to claim 1, wherein when the second casing and the first casing are in the buckled state, the limiting part and the butt joint part do not interfere with each other.

5. The casing structure of an electronic device according to claim 1, wherein the size of the limiting part is gradually reduced from the root to the free end, a through hole is formed in the first casing and is adjacent to the butt joint part, and the free end of the limiting part penetrates through the through hole.

6. The casing structure of an electronic device according to claim 1, wherein the number of the limiting parts is two, and the two limiting parts are located on the two opposite sides of the main body part respectively.

7. The casing structure of an electronic device according to claim 1, wherein a locking mechanism is arranged close to the second end and used for locking the second end with the first casing.

8. The casing structure of an electronic device according to claim 7, wherein the locking mechanism comprises a locking piece installed on the first casing or the second casing and clamping hooks arranged on the second casing or the first casing, and the locking piece can move between a locking position and an unlocking position so as to be separated from or clamped with the clamping hooks.

9. The casing structure of an electronic device according to claim 1, wherein the electronic device is a mobile terminal, the first casing is a battery casing, the second casing is a battery cover, and the first casing and the second casing are jointly used for accommodating a battery.

10. The casing structure of an electronic device according to claim 1, wherein when the first casing and the second casing are in the buckled state, the limiting surface is approximately parallel to the butt joint surface.
